(19) United States
(12) Patent Application Publication
(10) Pub. No.: US 2021/0086515 A1
(43) Pub. Date: Mar. 25, 2021

(54) ELECTROMECHANICAL TRANSDUCER ELEMENT, LIQUID DISCHARGE HEAD, LIQUID DISCHARGE DEVICE, LIQUID DISCHARGE APPARATUS, AND METHOD OF MAKING ELECTROMECHANICAL TRANSDUCER ELEMENT

(71) Applicant: Akira SHIMOFUKU, Kanagawa (JP)

(72) Inventor: Akira SHIMOFUKU, Kanagawa (JP)

(21) Appl. No.: 17/021,348

(22) Filed: Sep. 15, 2020

(30) Foreign Application Priority Data
Sep. 19, 2019 (JP) 2019-170648

(51) Int. Cl. B41J 2/14; H01L 41/083; H01L 41/09; H01L 41/187; H01L 41/277; H01L 41/318

(52) U.S. Cl. CPC B41J 2/14274; H01L 41/0831; H01L 41/318; H01L 41/1876; H01L 41/277; H01L 41/0973

(57) ABSTRACT

An electromechanical transducer element includes a first electrode on a diaphragm, an electromechanical transducer film on the first electrode, and a second electrode on the electromechanical transducer film. The electromechanical transducer film has a stacking structure. The electromechanical transducer film has a linear tapered shape that narrows from a first side facing the first electrode to a second side facing the second electrode in a cross section along a stacking direction.

### CROSS-REFERENCE TO RELATED APPLICATIONS

This patent application is based on and claims priority pursuant to 35 U.S.C. § 119(a) to Japanese Patent Application No. 2019-170648, filed on Sep. 19, 2019 in the Japan Patent Office, the entire disclosure of each of which is incorporated by reference herein.

### BACKGROUND

### Technical Field

Aspects of the present disclosure relate to an electromechanical transducer element, a liquid discharge head, a liquid discharge device, a liquid discharge apparatus, and a method of making an electromechanical transducer element.

### Related Art

An image recording apparatus such as a printer, a facsimile, or a copying machine or an inkjet recording apparatus used as an image forming apparatus discharges ink droplets from a recording head onto an object such as a sheet serving as a recording medium to from an image on the object. The recording head includes a nozzle, a pressure chamber, and an energy generator. The nozzle discharges ink droplets. The pressure chamber is communicated with the nozzle. The pressure chamber is also referred to as an ink channel, a pressure liquid chamber, a pressure chamber, a discharge chamber, a liquid chamber, or the like. The energy generator includes an electromechanical transducer element or an electrothermal transducer, a diaphragm, and an electrode. The electromechanical transducer element and the electrothermal transducer pressurize the ink in the pressure chamber. Examples of the electromechanical transducer element include a piezoelectric element. Examples of the electrothermal transducer include a heater. The diaphragm forms a wall surface of the ink channel. The electrode faces the diaphragm. The inkjet recording apparatus discharges ink droplets from the nozzles by pressurizing the ink in the pressure chamber with the energy generated by the energy generator.

In the case where an electromechanical transducer element is used as the energy generator, for example, a sol-gel method is known as a method for producing an electromechanical transducer film included in the electromechanical transducer element. The sol-gel method is a process technology capable of forming or film-forming an electromechanical transducer film made of a metal oxide more easily than a conventional vacuum film-forming method (for example, a sputtering method, an metal organic chemical vapor deposition (MO-CVD) method, a vacuum deposition method, or the like), a hydrothermal synthesis method, and an aerosol deposition (AD) method.

In the production of the electromechanical transducer film by the sol-gel method, a precursor of the electromechanical transducer film, that is, a so-called sol-gel solution is applied onto a substrate by a spin coating method or an inkjet method, and heat treatment is performed. In the production of the electromechanical transducer film by the sol-gel method, in order to prevent generation of cracks due to thermal shrinkage, the film thickness of the precursor formed per once is set to several tens of nanometers. In the production of the electromechanical transducer film by the sol-gel method, the above-described steps are repeated until a desired film thickness is obtained. In a conventional film forming method, an electromechanical transducer element is formed by forming an electromechanical transducer film on the entire surface of a substrate by a spin coating method and then performing photolithography and etching processes to form an element including a first electrode and a second electrode.

An electromechanical transducer film obtained after a general etching process has a substantially vertical cubic cross section together with electrodes sandwiching the electromechanical transducer film. In this case, the rigidity is constant between the end portion side and the central portion of the electromechanical transducer film, and the end portion side restrains deformation displacement of the central portion. Accordingly, the amount of displacement of the electromechanical transducer element as a whole is reduced.

On the other hand, there is known a technique in which an electromechanical transducer element has a shape (cylindrical shape) in which a film thickness gradually increases from an end portion to a central portion of an actuator portion in a cross section of the actuator portion. The rigidity gradually increases from the end portion toward the central portion of the actuator portion. In the technique, the rigidity characteristics of the actuator portion of the electromechanical transducer element are defined and realized to obtain efficient deformation displacement.

### SUMMARY

In an aspect of the present disclosure, there is provided an electromechanical transducer element that includes a first electrode on a diaphragm, an electromechanical transducer film on the first electrode, and a second electrode on the electromechanical transducer film. The electromechanical transducer film has a stacking structure. The electromechanical transducer film has a linear tapered shape that narrows from a first side facing the first electrode to a second side facing the second electrode in a cross section along a stacking direction.

### BRIEF DESCRIPTION OF THE DRAWINGS

The aforementioned and other aspects, features, and advantages of the present disclosure would be better understood by reference to the following detailed description when considered in connection with the accompanying drawings, wherein:

FIGS. 1A and 1B are schematic cross-sectional views of an electromechanical transducer element according to an embodiment of the present disclosure;

FIG. 2 is a schematic cross-sectional view of a liquid discharge head according to another embodiment of the present disclosure;

FIG. 3 is a schematic cross-sectional view of a liquid discharge head according to another embodiment of the present disclosure;

FIG. 4A is a schematic cross-sectional view of an electromechanical transducer element according to an embodiment of the present disclosure;

FIG. 4B is a schematic cross-sectional view of an electromechanical transducer element according to a comparative example;

FIG. 4C is a schematic view of an example of displacement and deformation of the electromechanical transducer element illustrated in FIG. 4A; and

FIG. 4D is a schematic cross-sectional view of an example of displacement and deformation of the electromechanical transducer element according to the comparative example of FIG. 4B;

FIG. 5 is a graph of a measurement example of the amounts of displacement in FIGS. 4A, 4B, 4C, and 4D;

FIGS. 6A, 6B, and 6C are schematic cross-sectional views of an electromechanical transducer element according to an embodiment of the present disclosure to illustrate an example of a method of manufacturing the electromechanical transducer element;

FIGS. 7A, 7B, and 7C are schematic cross-sectional views of an electromechanical transducer element according to an embodiment of the present disclosure to illustrate an example of a method of manufacturing the electromechanical transducer element;

FIG. 8 is a flowchart of a method of manufacturing an electromechanical transducer element according to an embodiment of the present disclosure;

FIGS. 9A, 9B, and 9C are schematic cross-sectional views of an electromechanical transducer element according to an embodiment of the present disclosure to illustrate an example of a method of manufacturing the electromechanical transducer element;

FIGS. 10A, 10B, and 10C are schematic cross-sectional views of an electromechanical transducer element according to an embodiment of the present disclosure to illustrate an example of a method of manufacturing the electromechanical transducer element;

FIG. 11 is a schematic cross-sectional view of an example of an electromechanical transducer element according to an embodiment of the present disclosure;

FIG. 12 is another schematic cross-sectional view of the electromechanical transducer element according to the embodiment of the present disclosure;

FIG. 13 is another schematic cross-sectional view of the electromechanical transducer element according to the embodiment of the present disclosure;

FIG. 14 is another schematic cross-sectional view of the electromechanical transducer element according to the embodiment of the present disclosure;

FIG. 15 is a plan view of a main part of a liquid discharge apparatus according to an embodiment of the present disclosure;

FIG. 16 is a side view of a main part of a liquid discharge apparatus according to an embodiment of the present disclosure;

FIG. 17 is a plan view of an example of a liquid discharge device according to an embodiment of the present disclosure;

FIG. 18 is a front view of a liquid discharge device according to an embodiment of the present disclosure;

FIG. 19 is a perspective view of a liquid discharge apparatus according to an embodiment of the present disclosure;

FIG. 20 is a side view of a liquid discharge apparatus according to an embodiment of the present disclosure; and

FIG. 21 is a graph of a P-E hysteresis curve of an electromechanical transducer element obtained in Example 1.

The accompanying drawings are intended to depict embodiments of the present disclosure and should not be interpreted to limit the scope thereof. The accompanying drawings are not to be considered as drawn to scale unless explicitly noted.

### DETAILED DESCRIPTION

In describing embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner and achieve similar results. As used herein, the singular forms “a”, “an”, and “the” are intended to include the plural forms as well, unless the context clearly indicates otherwise.

Although the embodiments are described with technical limitations with reference to the attached drawings, such description is not intended to limit the scope of the disclosure and all of the components or elements described in the embodiments of this disclosure are not necessarily indispensable.

Hereinafter, an electromechanical transducer element, a liquid discharge head, a liquid discharge device, a liquid discharge apparatus, and a method of manufacturing an electromechanical transducer element according to embodiments of the present disclosure are described with reference to the drawings. Embodiments of the present disclosure are not limited to embodiments hereinafter described, and changes such as other embodiments, additions, modifications, and deletions may be made within the scope conceivable by those skilled in the art. Any aspects are included in the scope of the present disclosure as long as the actions and effects of the present disclosure are exhibited.

### Electromechanical Transducer Element, Liquid Discharge Head, and Method of Making Electromechanical Transducer Element

An electromechanical transducer element according to an embodiment of the present disclosure includes: a first electrode on a diaphragm; an electromechanical transducer film on the first electrode; and a second electrode on the electromechanical transducer film. The electromechanical transducer film has a stacking structure and has a linear tapered shape that narrows from the first electrode side to the second electrode side in a cross section along a stacking direction.

As the electromechanical transducer element using the electromechanical transducer film, for example, there are known various devices such as a liquid discharge head, an actuator for driving a stage, an angular velocity sensor, an acceleration sensor, a deflection mirror, a fine adjustment device for a hard disk drive (HDD) head, a ferroelectric memory element, and a micropump, and a microelectronic application. An electromechanical transducer element according to the present embodiment is particularly preferably used as a liquid discharge head.

The liquid discharge head according to an embodiment of the present disclosure includes a nozzle to discharge liquid, a pressure chamber communicating with the nozzle, and a pressure generator to generate pressure in the liquid in the pressure chamber. The liquid discharge head includes, as the pressure generator, the electromechanical transducer element according to the present embodiment.

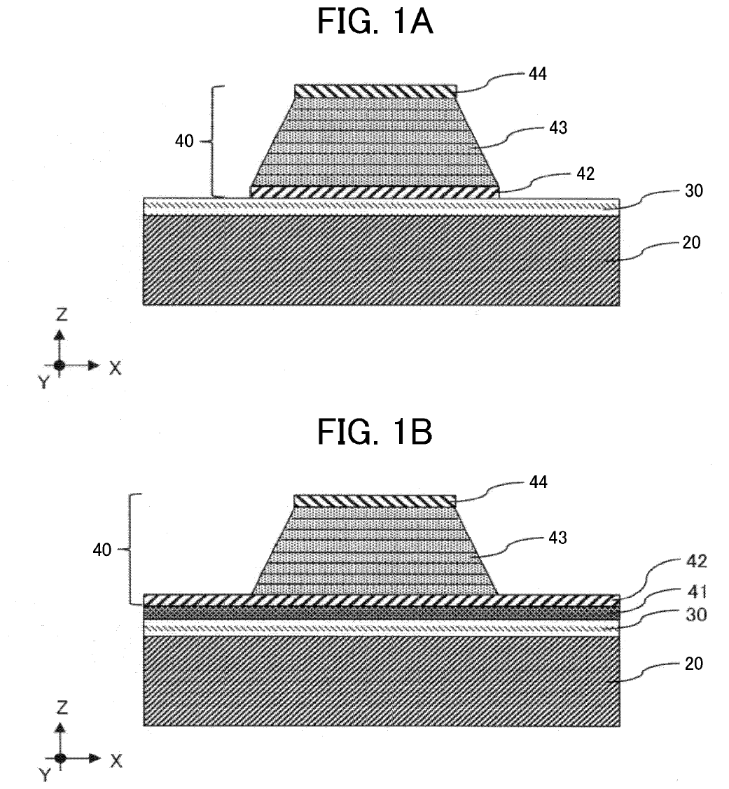

FIGS. 1A and 1B are cross-sectional views of the electromechanical transducer element according to the present embodiment. In FIG. 1A, a substrate (or a pressure chamber substrate) 20, a diaphragm 30, a first electrode 42, an electromechanical transducer film 43, and a second electrode 44 are illustrated. An electromechanical transducer element 40 includes a first electrode 42, an electromechanical transducer film 43, and a second electrode 44. In FIG. 1B, an adhesion layer 41 is illustrated.

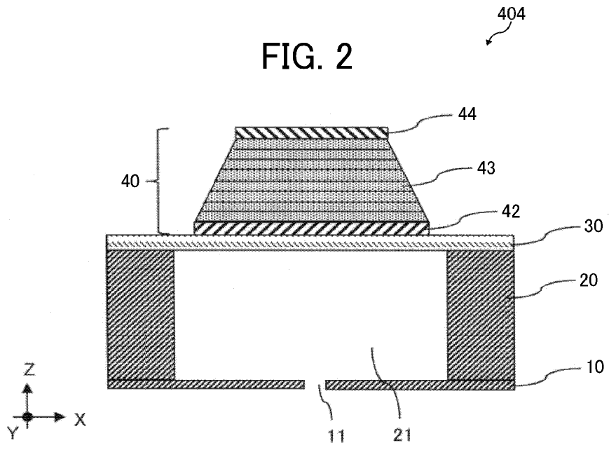

FIG. 2 is a cross-sectional view of a liquid discharge head using the electromechanical transducer element. A liquid discharge head 404 illustrated in FIG. 2 includes a nozzle plate 10, the substrate 20, the diaphragm 30, and the electromechanical transducer element 40. The nozzle plate 10 has a nozzle 11 to discharge ink droplets. The nozzle plate 10, the substrate 20, and the diaphragm 30 constitute a pressure chamber 21 that communicates with the nozzle 11. The pressure chamber 21 may be referred to as an ink channel, a pressurized liquid chamber, a pressurizing chamber, a discharge chamber, a liquid chamber, or the like. The diaphragm 30 constitutes part of a wall surface of the ink channel.

The electromechanical transducer element 40 has a function of pressurizing the ink in the pressure chamber 21. In the electromechanical transducer element 40, when a voltage is applied between the first electrode 42 and the second electrode 44, the electromechanical transducer film 43 is mechanically displaced. As the electromechanical transducer film 43 is mechanically displaced, the diaphragm 30 is deformed and displaced, for example, in a lateral direction (D31 direction) to pressurize ink in the pressure chamber 21. Thus, ink droplets are discharged from the nozzles 11.

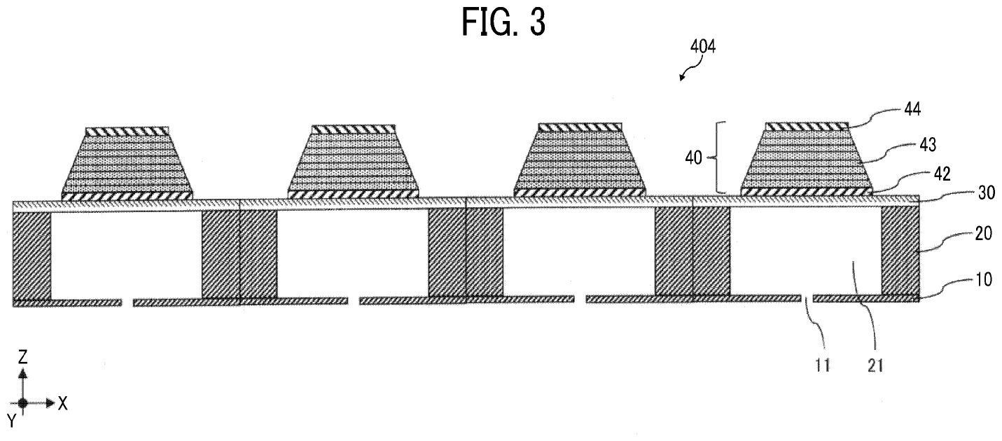

As illustrated in FIG. 3, a plurality of liquid discharge heads may be arranged side by side to form a liquid discharge head 404. In the liquid discharge head 404 according to the present embodiment, the first electrode 42 may be a common electrode and the second electrode 44 may be an individual electrode. In the liquid discharge head 404 according to the present embodiment, the first electrode 42 may be an individual electrode and the second electrode 44 may be a common electrode.

The electromechanical transducer film 43 according to the present embodiment has a stacking structure, and has a linear tapered shape that narrows from the first electrode side to the second electrode side in a cross section along the stacking direction. The cross-sectional view of FIG. 1 is a cross-sectional view along the stacking direction. The electromechanical transducer film 43 has a shape in which wall surfaces on both end sides in the X-axis direction are linearly tapered.

In the present embodiment, the electromechanical transducer film 43 has a long side and a short side when the electromechanical transducer element is viewed from a direction vertical to a surface direction. The term “cross section along the stacking direction” represents a cross section along a short direction. In addition, the term “surface direction” is also referred to as a surface of the substrate or a surface of the diaphragm.

In the cross-sectional view illustrated in FIG. 1, the X-axis is the short direction, the Y-axis is the longitudinal direction, and the Z-axis is the stacking direction, and the wall surfaces of the electromechanical transducer film 43 on both end sides in the short direction (X-axis direction) are linearly tapered. The stacking direction is also synonymous with a thickness direction, a displacement direction, and the like. Embodiments of the present disclosure are not limited to the shape, and for example, the wall surfaces of the electromechanical transducer film on both end sides in the longitudinal direction (Y-axis direction) may be linearly tapered. In some embodiments, he wall surfaces of the electromechanical transducer film on both end sides may be tapered in both the longitudinal direction and the short direction.

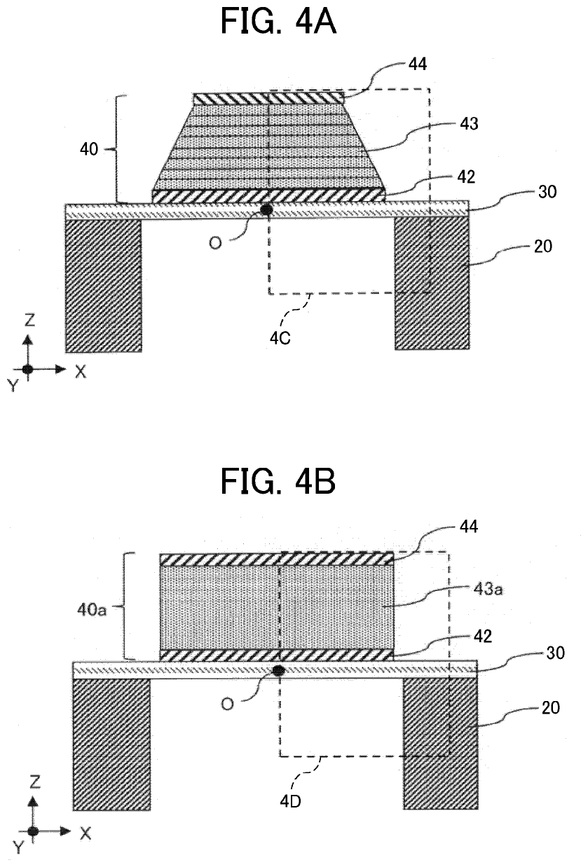

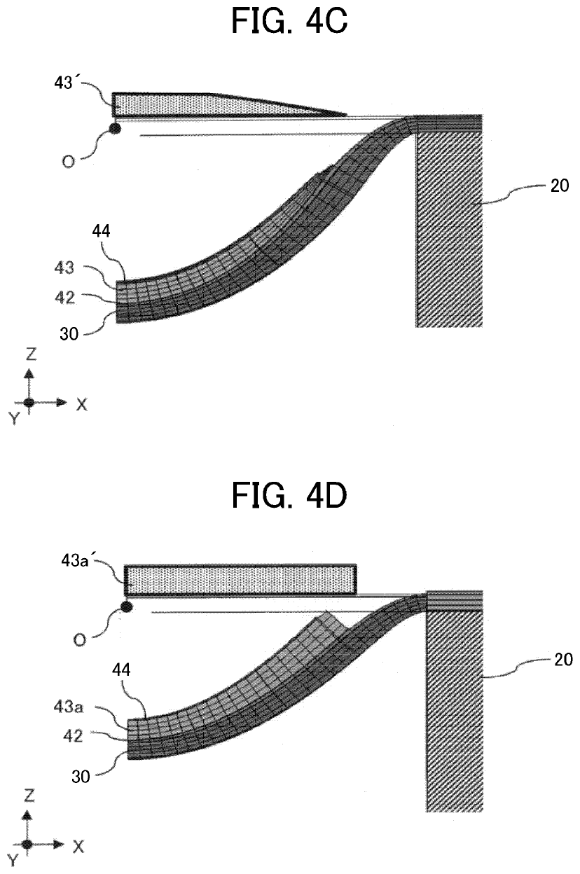

FIGS. 4A, 4B, 4C, and 4D are cross-sectional views for schematically illustrating the deformation of the electromechanical transducer film according to the present embodiment.

FIG. 4A is a cross-sectional view of an electromechanical transducer element according to the present embodiment. FIG. 4C is an enlarged schematic view of a main part of the electromechanical transducer element of FIG. 4A. Similarly, FIG. 4B is a cross-sectional view of an electromechanical transducer element according to a comparative example. FIG. 4D is an enlarged schematic view of a main part of the electromechanical transducer element of FIG. 4B. In FIGS. 4A, 4B, 4C, and 4D, a point O indicates the position of the center of a vibration region in the diaphragm 30.

In the examples of displacement illustrated in FIGS. 4C and 4D, the scale in the vertical direction is magnified, for example, 50 times so that the difference in deformation can be seen.

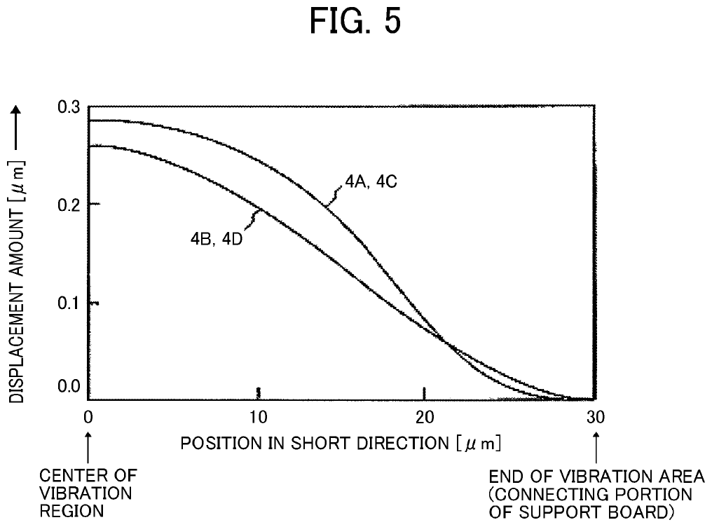

FIG. 5 is a graph of an example of the amount of displacement in the deformation of the electromechanical transducer film according to present embodiment illustrated in FIGS. 4A and 4C and the electromechanical transducer film according to the comparative example illustrated in FIGS. 4B and 4D. In the example illustrated in FIG. 5, the amount of displacement (4A and 4C) of the present embodiment in which the electromechanical transducer film is tapered at both ends in the short direction (X-axis direction) and the amount of displacement (4B and 4D) of the comparative example are illustrated. The amount of displacement in FIG. 5 is a value obtained by measuring the amount of displacement of the diaphragm 30 and the electromechanical transducer element with a laser Doppler meter.

The measurement results represent the case in which the electromechanical transducer film is tapered on both ends in the short direction. However, the same tendency is observed also in the case in which the electromechanical transducer film is tapered on both ends in the longitudinal direction. In FIGS. 4C and 4D, electromechanical transducer films 43′ and 43a′ indicate a state where no voltage is applied.

As illustrated in FIG. 5, according to the present embodiment, the amount of displacement can be increased as compared with the comparative example. In the comparative example, since the electromechanical transducer film 43a is formed in a rectangular shape in cross section (see FIG. 4B) and the film thickness is substantially uniform, the rigidity is substantially constant regardless of the location or position. Accordingly, the electromechanical transducer film 43a may hamper deformation of the diaphragm 30 in the vicinity of an end of the electromechanical transducer film 43a.

On the other hand, since the electromechanical transducer film 43 according to the present embodiment is tapered in cross section, the film thickness decreases toward an end of the electromechanical transducer film 43, thus decreasing the rigidity in the vicinity of the end of the electromechanical transducer film 43. Accordingly, the electromechanical transducer film 43 can increase the amount of displacement of the diaphragm 30 without hampering the deformation of the diaphragm 30 in the vicinity of an end of the electromechanical transducer film.

Further, according to the present embodiment, the displacement efficiency with respect to the film thickness of the electromechanical transducer film can be maximized. In the example illustrated in FIG. 5, the thickness of the electromechanical transducer film 43 in the present embodiment is equal to the thickness of the electromechanical transducer film 43a in the comparative example. The amount of displacement in the present embodiment is larger than the amount of displacement in the comparative example having the electromechanical transducer film with the same thickness. Accordingly, the displacement efficiency can be improved as compared with the comparative example, and good discharge performance can be obtained.

In addition, a drive portion that is a stacking structure portion from the diaphragm 30 to the second electrode 44 via the electromechanical transducer film 43 and is actually deformed and displaced when voltage is applied is also referred to as a “structure”.

Hereinafter, an example of each configuration of the electromechanical transducer element of the present embodiment is described in detail.

### Substrate and Diaphragm

As the substrate 20, for example, a silicon substrate can be used. The substrate 20 preferably has a thickness of, for example, 100 μm to 600 μm.

Examples of a material of the diaphragm 30 include a material obtained by insulating a surface of silicon. Examples of a material for insulating the substrate surface includes a silicon oxide film, a silicon nitride film, a silicon oxynitride film, a film obtained by stacking the silicon oxide film, the silicon nitride film, and the silicon oxynitride film, or the like having a thickness of about several hundred nanometers to about several micrometers. In consideration of a difference in thermal expansion, a ceramic film such as an aluminum oxide film or a zirconia film may be used.

The silicon-based insulating film for insulating the substrate surface can be formed by chemical vapor deposition (CVD), thermal oxidation of silicon, or the like. A metal oxide film such as an aluminum oxide film for insulating the surface of the diaphragm 30 can be formed by a sputtering method or the like.

### Sticking Layer

In the present embodiment, the adhesion layer 41 may be formed on the diaphragm 30. The adhesion layer 41 is a layer made of, for example, Ti, TiO₂, TiN, Ta, Ta₂O₅, Ta₃N₅, or the like, and has a function of improving adhesion between the first electrode 42 and the diaphragm 30. FIG. 1B illustrates an example in which the adhesion layer 41 is formed.

### First Electrode

As a material of the first electrode 42, a metal or the like having high heat resistance can be used. For example, a platinum group metal having low reactivity, such as ruthenium (Ru), rhodium (Rh), palladium (Pd), osmium (Os), iridium (Ir), or platinum (Pt), an alloy material containing any of these platinum group metals, or the like can be used.

After such a metal layer is formed, a conductive oxide layer may be stacked on the metal layer for use. Examples of conductive oxides include composite oxides represented by Chemical Formula ABO₃, in which A as a main component is Sr, Ba, Ca, or La, and B as another main component is Ru, Co, or Ni.

Examples of the conductive oxides include SrRuO₃, CaRuO₃, (Sr₁₋ₓ, Caₓ) O₃ which is a solid solution of SrRuO₃ or CaRuO₃, and LaNiO₃, SrCoO₃, and (La, Sr) (Ni_{1-y}, Co_{y}) O₃ (y may be 1) which is a solid solution of LaNiO₃ or SrCoO₃. Other oxides include IrO₂ and RuO₂.

The first electrode 42 can be produced by, for example, a method such as a sputtering method or a vacuum deposition method such as vacuum deposition. Since the first electrode 42 is electrically connected as a common electrode when a signal is input to the electromechanical transducer element 40, an insulator or a conductor having an insulated surface can be used for the diaphragm 30 below the second electrode.

The shape of the first electrode 42 can be changed as appropriate and may be patterned as illustrated in FIG. 1A. Alternatively, the first electrode 42 may be formed as illustrated in FIG. 1B.

The film thickness is, for example, preferably 0.05 μm to 1 μm, and more preferably 0.1 μm to 0.5 μm.

### Electromechanical Conversion Film

Next, the electromechanical transducer film according to the present embodiment is described together with an example of a manufacturing method. Here, an example of manufacturing the electromechanical transducer element illustrated in FIG. 1B is described.

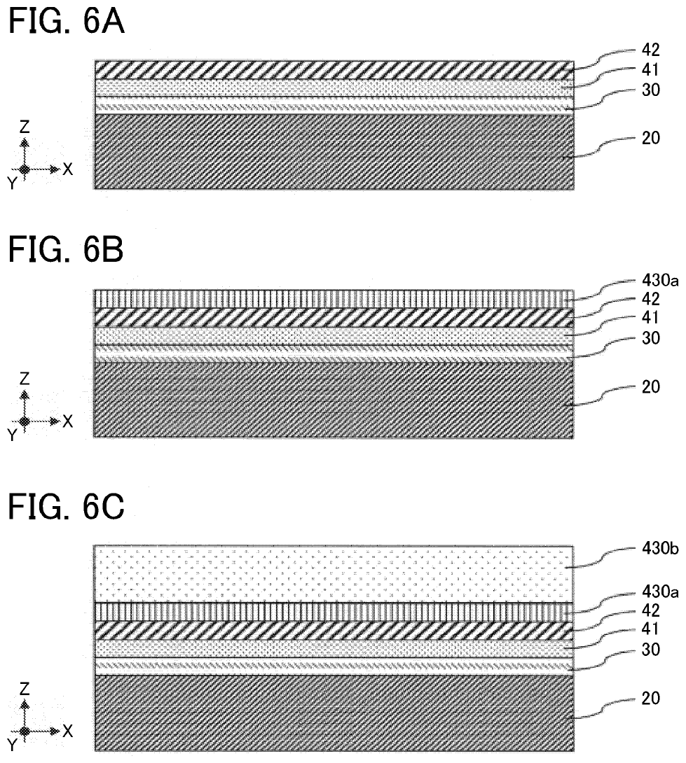

FIGS. 6A to 10C illustrate the present example.

First, in the step illustrated in FIG. 6A, the adhesion layer 41 and the first electrode 42 are sequentially stacked on the surface of the substrate 20 having the diaphragm 30. As described above, the first electrode 42 may have a single-layer structure made of a platinum group metal or an alloy material containing the platinum group metal, or a two-layer structure in which a conductive oxide layer is subsequently stacked on the platinum group metal or the alloy material.

Next, in the step illustrated in FIG. 6B, an electromechanical transducer film having a thickness of about several nanometers is formed as a seed layer 430a on the entire surface of the first electrode 42. The seed layer 430a is preferably formed as a coating film by applying a precursor sol-gel solution by a sol-gel method in terms of ease of a film forming process on the entire surface of the first electrode 42. As a method of forming the coating film, there are methods such as spin coating and spray coating, and an inkjet printing method. For example, in order to form the coating film on the entire surface of the first electrode 42 and ensure uniformity of the in-plane film thickness, coating by spin coating is desirable.

The seed layer 430a formed by chemical solution deposition (CSD) such as spin coating is preferably formed first as an amorphous ceramic film. In such a case, it is effective to make the finally crystallized piezoelectric ceramic film to be subsequently stacked have a target film quality (high crystallinity and high orientation). In order to make the seed layer 430a amorphous, the heat treatment of the coating film of the precursor solution is performed up to the drying or thermal decomposition at the first heating temperature, that is, only the drying of solvent components or the removal of organic substance. The heat treatment at the first heating temperature can be performed by using, for example, a hot plate, an infrared lamp irradiation device, or the like, and can be performed by a heating mechanism capable of controlling a drying temperature, a heating rate, a heating time, or the like.

Next, as illustrated in FIG. 6C, the precursor sol-gel solution is applied on the entire surface of the seed layer 430a by the sol-gel method. Examples of the method for forming the coating film include general methods such as spin coating and spray coating, and an inkjet printing method. However, in order to form the precursor coating film 430b on the entire surface of the seed layer 430a and to ensure a uniform in-plane thickness as in the case of the formation of the seed layer described above, application by spin coating is desirable.

The composition of the precursor solution is not particularly limited, and may be arbitrarily selected depending on the electromechanical transducer film 43 to be formed. In the case of the electromechanical transducer film described above, it is usually preferable that the electromechanical transducer film is formed of a metal composite oxide film.

For example, lead zirconate titanate (PZT) can be used as the material of the electromechanical transducer film 43. PZT is a solid solution of lead zirconate (PbZrO₃) and lead titanate (PbTiO₃). For example, a PZT, in which the ratio of PbZrO₃ and PbTiO₃ is 53:47, can be used, which is represented by a chemical formula of Pb(Zr_{0.53}, Ti_{0.47})O₃ or generally represented as PZT (53/47). The characteristics of PZT vary depending on the ratio of PbZrO₃ to PbTiO₃.

When PZT is used as the electromechanical transducer film 43, lead acetate-3-hydrate, a zirconium alkoxide compound, and a titanium alkoxide compound may be used as starting materials. The starting materials are dissolved in a common solvent (main solvent) to prepare a PZT precursor sol-gel solution. The amounts of the lead acetate-3-hydrate, the zirconium alcoxide compound, and the titanium alcoxide compound to be mixed can be appropriately selected by those skilled in the art according to the desired composition of PZT (the ratio of PbZrO₃ to PbTiO₃).

The metal alkoxide compound is easily decomposed by moisture in the air. Therefore, acetylacetone, acetic acid, diethanolamine, or the like may be added as a stabilizer to the PZT precursor sol-gel solution.

Examples of the material of the main solvent include 2-methoxyethanol, 2-n-butoxyethanol, and 2-propanol (isopropyl alcohol).

As the material of the electromechanical transducer film 43, barium titanate or the like may be used, for example. In such a case, a barium titanate precursor sol-gel solution can be prepared by dissolving barium alkoxide compound or a titanium alkoxide compound as a starting material in a common solvent. For example, a solid solution of barium titanate and bismuth perovskite may be used.

These materials are composite oxides represented by the general formula ABO₃, where A as a main component is Pb, Ba, Sr, or Bi, and B as another main component is Ti, Zr, Sn, Ni, Zn, Mg, or Nb. For example, the materials are represented by (Pb₁₋ₓ, Baₓ) (Zr, Ti) O₃ and (Pb₁₋ₓ, Srₓ) (Zr, Ti) O₃, which are cases where Pb at the A site is partially substituted with Ba or Sr. The substitution is enabled in a bivalent element and an effect thereof is to reduce characteristic deterioration by the evaporation of the lead during heat treatment.

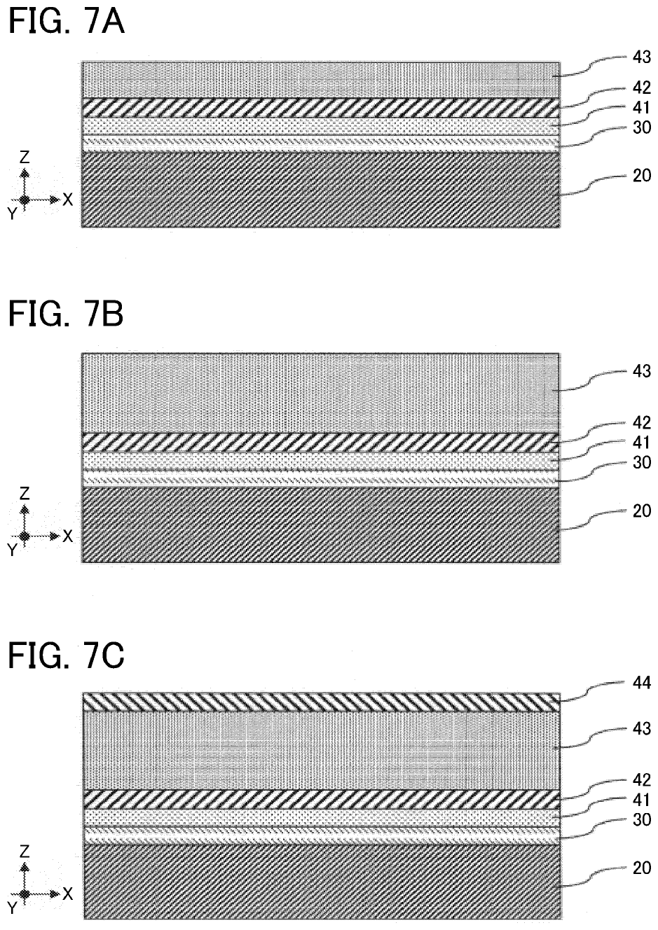

Next, as illustrated in FIG. 7A, heat treatment is performed on the precursor coating film 430b. The specific content of the heat treatment is not particularly limited. For example, the heat treatment may be a step of heating and drying the precursor coating film 430b at a first heating temperature, a thermal decomposition step of heating the precursor coating film 430b at a second temperature higher than the first temperature to decompose organic substance and the like contained in the precursor coating film 430b, or a crystallizing step of heating the precursor coating film 430b at a third temperature higher than the second temperature to crystallize substances constituting the precursor coating film 430b.

In order to obtain sufficient performance of the electromechanical transducer film 43, it is preferable to perform the steps up to the crystallization step. In the crystallizing step, the seed layer 430a and the precursor coating film 430b are integrated to form the same electromechanical transducer film 43.

In addition, specific heat treatment conditions are not particularly limited and may vary depending on the type of the precursor solution used. As a means for drying and thermally decomposing the precursor coating film 430b, for example, a heating mechanism such as a hot plate or an infrared lamp irradiation device can be used. In addition, the heating temperature in the thermal decomposition is selected to be a temperature of about 350° C. to about 450° C., thus allowing the thermal decomposition of the organic substance contained in the gelled precursor coating film 430b to proceed to form an amorphous piezoelectric ceramic film.

The crystallization is to crystallize the electro-mechanical conversion film that has been made amorphous by thermal decomposition, and the electro-mechanical conversion film that has been thermally decomposed is further sintered and crystallized at a high temperature. As the crystallization means, for example, a heating mechanism such as a hot plate or an infrared lamp irradiation device can be used as in the drying and thermal decomposition step. The heating temperature in crystallization varies depending on the type of the sol-gel solution used and is not particularly limited. In general, an amorphous electromechanical transducer film can be crystallized by selecting a temperature higher than the temperature used in thermal decomposition.

The thickness of the electromechanical transducer film 43 obtained by one film formation is preferably about 50 nm to about 100 nm. The concentration of the precursor solution is preferably optimized in view of the relationship between the film formation area and the coating amount of the precursor solution.

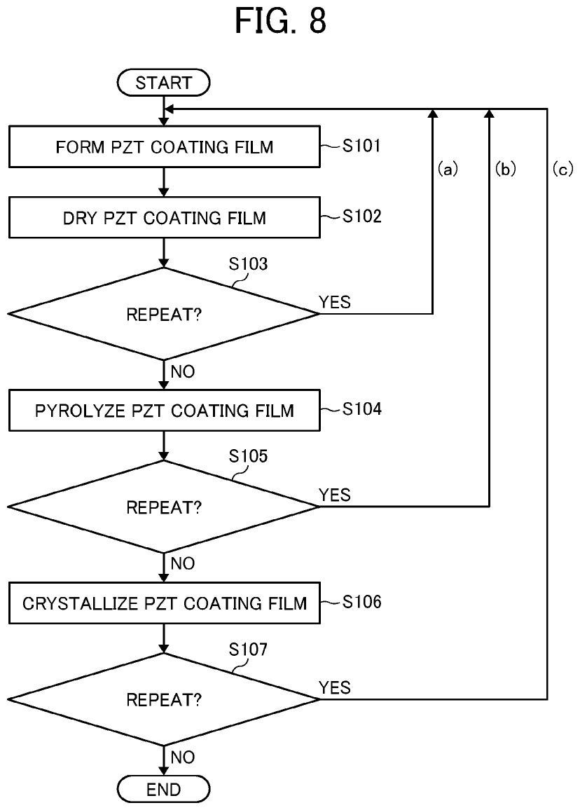

In the present embodiment, the timing of crystallization of the electromechanical transducer film formed by application of the precursor solution is not particularly limited. Here, an example of the timing of crystallization of the electromechanical transducer film formed by applying the PZT coating liquid (PZT precursor solution) is described with reference to the flowchart of FIG. 8. Here, a case where the electromechanical transducer film is PZT is described as an example.

In FIG. 8, arrows (a) to (c) indicate repetition of the steps, and the steps can be repeated arbitrarily or at any timing. In addition, in FIG. 8, the preparation of the substrate 20 on which the first electrode 42 is a start point, and the formation of the desired electromechanical transducer film 43 on the first electrode 42 is an end point. The timing of repetition can be appropriately changed, and examples thereof include the following.

As a first example, the step (S101) of forming the PZT coating film by coating the first electrode 42 (or the PZT coating film after drying, thermal decomposition, or crystallizing) with the PZT precursor solution may be repeatedly performed at any timing after each of the steps of drying (S102), thermal decomposition (S103), and crystallizing (S104).

For example, only the step (S101) of forming a PZT coating film and the step (S102) of drying the PZT coating film are repeatedly stacked by a predetermined number of times (arrow (a) in FIG. 8). Then, thermal decomposition (S103) is carried out at any timing, and then, crystallization (S104) can be carried out. In some cases, after the crystallizing step (S104), the process can return to the step (S101) of forming a PZT coating film and the drying step (S102), and the PZT coating film is repeatedly formed and stacked (arrow (c) in FIG. 8).

In addition, as a modified example thereof, the step (S101) of forming the PZT coating film, the drying (S102), and the thermal decomposition (S103) are repeated a predetermined number of times to stack the PZT coating films (arrow of (b) in FIG. 8). Then, the crystallization (S104) can be performed at any timing. In some cases, after the crystallizing step (S104), the process returns to the step (S101) of forming the PZT coating film, the drying step (S102), and the thermal decomposition step (S103), and the film formation and stacking are repeated (arrow (c) in FIG. 8).

As a second example, the step of forming a PZT coating film (S101), drying (S102), thermal decomposition (S103), and crystallizing (S104) are repeated in this order to form and stack films (arrow (c) in FIG. 8). The above-described steps are repeated until the PZT film has a desired thickness.

In the present embodiment, the electromechanical transducer film is stacked or formed by spin coating.

In the case of forming a cylindrical shape by repeatedly applying a precursor liquid by an inkjet method as conventionally performed, it may be difficult to increase the film thickness while maintaining the cylindrical shape. In such a conventional technique, it is disadvantageous in accuracy of patterning in which the precursor liquid of the electromechanical transducer film is repeatedly applied to a desired portion. In such a conventional technique, it may be also disadvantageous in productivity, and further improvement may be needed.

On the other hand, according to the present embodiment, by using the spin coating method, the patterning accuracy can be increased by the photolithography and etching processes, and high productivity can be ensured. In addition, the thickness of the electromechanical transducer film can be increased by several micrometers to several tens of micrometers. Further, even when the film thickness is increased, the occurrence of cracks or the like in the electromechanical transducer film can be restrained, thus allowing a high-quality electromechanical transducer element to be obtained.

In the case of using a spin coating method, an electromechanical transducer film made of a metal oxide can be formed on a substrate more easily than a sputtering method, a vacuum deposition method such as a metal organic chemical vapor deposition (MO-CVD) method or a vacuum deposition method, and an aerosol deposition (AD) method. In addition, as described above, compared to an inkjet method in which a precursor material of an electromechanical transducer film is directly applied onto a desired shape pattern by an inkjet method to form a film, it is easy to increase the thickness of the electromechanical transducer film. In addition, high patterning accuracy is maintained, thus ensuring high productivity due to high yield.

In the present embodiment, an electromechanical transducer film having a stacking structure is obtained by repeating application of the precursor solution by spin coating and heating. Whether the electromechanical transducer film has been produced by the spin coating method can be determined by observing a cross section of the produced electromechanical transducer film. The cross section of the electromechanical transducer film can be observed by, for example, a scanning electron microscope (SEM) or a transmission electron microscope (TEM).

The electromechanical transducer film 43 formed through the above-described process can be thickened by repeating the same process. That is, as illustrated in FIG. 8, for example, by repeating the steps illustrated in FIGS. 6C and 7A a necessary number of times to further increase the thickness of the electromechanical transducer film 43, the electromechanical transducer film 43 having a thickness of about several micrometers to several tens of micrometers as illustrated in FIG. 7B can be formed.

Next, as illustrated in FIG. 7C, the second electrode 44 is formed on the electromechanical transducer film 43. The material or the film thickness of the second electrode 44 is not particularly limited, but may be the same as the configuration of the first electrode 42, for example. The second electrode 44 is formed by, for example, a sputtering method or the like.

In order to individualize the stacked body including the first electrode 42, the electromechanical transducer film 43, and the second electrode 44, for example, after the second electrode 44 is formed, the electromechanical transducer film 43 and the second electrode 44 are patterned by etching.

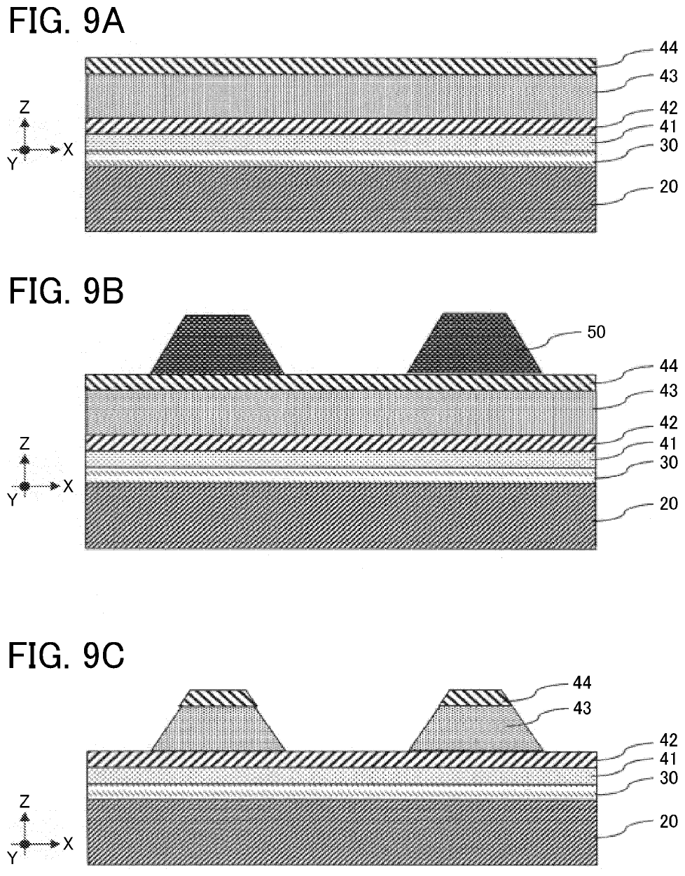

Next, the cross-sectional shape of the electromechanical transducer film 43 is tapered. An example is described below with reference to FIG. 9. FIG. 9A depicts the same state as FIG. 7C, in which the second electrode 44 is formed on the electromechanical transducer film 43.

Next, in the step illustrated in FIG. 9B, the photoresist layer 50 is patterned by a known photolithography method to form a resist pattern. At this time, as a feature of the present embodiment, the resist pattern formed on the second electrode 44 has a tapered shape similarly to the pattern of the electromechanical transducer element 40 formed on the substrate 20.

The thickness of the photoresist layer 50 is determined by the selected etching ratio of the electromechanical transducer film 43 and the second electrode 44 to the photoresist layer 50.

The resist pattern is formed in accordance with the layout of the pressure chambers 21 illustrated in FIG. 2 or 3. The resist pattern having a tapered cross-sectional shape is formed by selecting a photoresist material for forming the photoresist layer 50, optimizing exposure conditions in photolithography, or optimizing development conditions.

Next, etching is performed to obtain the shape illustrated in FIG. 9C. As illustrated in FIG. 9C, in a region where the resist pattern is not formed on the second electrode 44, the electromechanical transducer film 43 and the second electrode 44 are removed by dry etching or the like to expose the first electrode 42. The pattern of the removed portion has an inverted tapered shape obtained by inverting the pattern of the desired electromechanical transducer element 40.

On the other hand, in the region covered with the resist pattern, the resist pattern remaining after patterning such as dry etching is removed to form a predetermined pattern of the electromechanical transducer element 40 including the first electrode 42, the electromechanical transducer film 43, and the second electrode 44 on the substrate 20. The cross-sectional shape of the electromechanical transducer film 43 at this time may be a tapered shape.

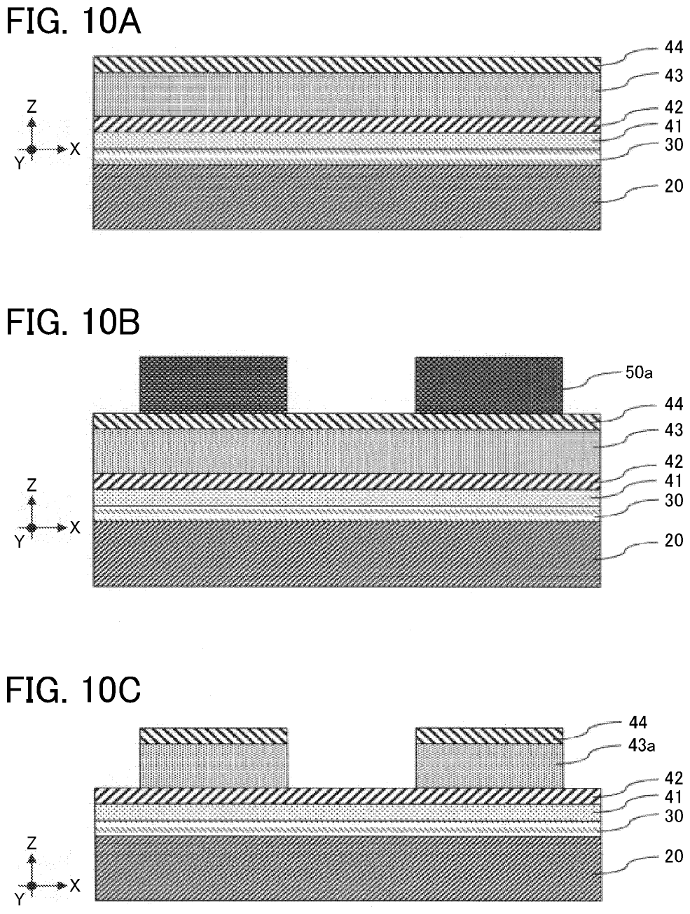

For reference, a comparative example of patterning of an electromechanical transducer film in an electromechanical transducer element is described with reference to FIGS. 10A, 10B, and 10C. FIGS. 10A, 10B, and 10C correspond to FIGS. 9A, 9B, and 9C, respectively.

In the comparative example illustrated in FIGS. 10A, 10B, and 10C, a resist pattern is formed as illustrated in FIG. 10B. That is, the cross-sectional shape of the resist pattern in the lateral direction (or short direction) is a cubic shape, and the bottom side and the upper side have the same length. By performing etching using such a resist pattern, the shape illustrated in FIG. 10C is obtained. Such an electromechanical transducer film is illustrated in FIGS. 4B and 4D.

### Second Electrode

The second electrode 44 may have the same configuration as the first electrode 42. For example, a platinum group metal such as ruthenium (Ru), rhodium (Rh), palladium (Pd), osmium (Os), iridium (Tr), or platinum (Pt) (Pt), or an alloy material containing any of these platinum group metals can be used. After such a metal layer is formed, a conductive oxide layer may be stacked on the metal layer for use. Similarly to the first electrode 42, the second electrode 44 can be produced by, for example, a sputtering method or a vacuum deposition method such as vacuum deposition.

As described above, according to the present embodiment, there can be provided an electromechanical transducer element having a high amount of displacement and high productivity.

As described above, the method of manufacturing an electromechanical transducer element according to the present embodiment includes the steps of forming a first electrode, forming an electromechanical transducer film, and forming a second electrode. In the step of forming the electromechanical transducer film, the electromechanical transducer film having a stacking structure is formed by a spin coating method, and a linear tapered shape narrowing from the first electrode side to the second electrode side is formed in a cross section of the electromechanical transducer film along the stacking direction.

According to the method of manufacturing an electromechanical transducer element of the present embodiment, an electromechanical transducer element having a high amount of displacement can be obtained with high productivity. In addition, an electromechanical transducer film having a thickness of several micrometers to several tens of micrometers can be manufactured. Further, even when the film thickness is increased, the occurrence of cracks or the like in the electromechanical transducer film can be restrained, thus allowing a high-quality electromechanical transducer element to be obtained.

### Other Examples

Next, other examples of the electromechanical transducer element according to the present embodiment are described. Redundant descriptions of the same matters as those described above may be omitted below.

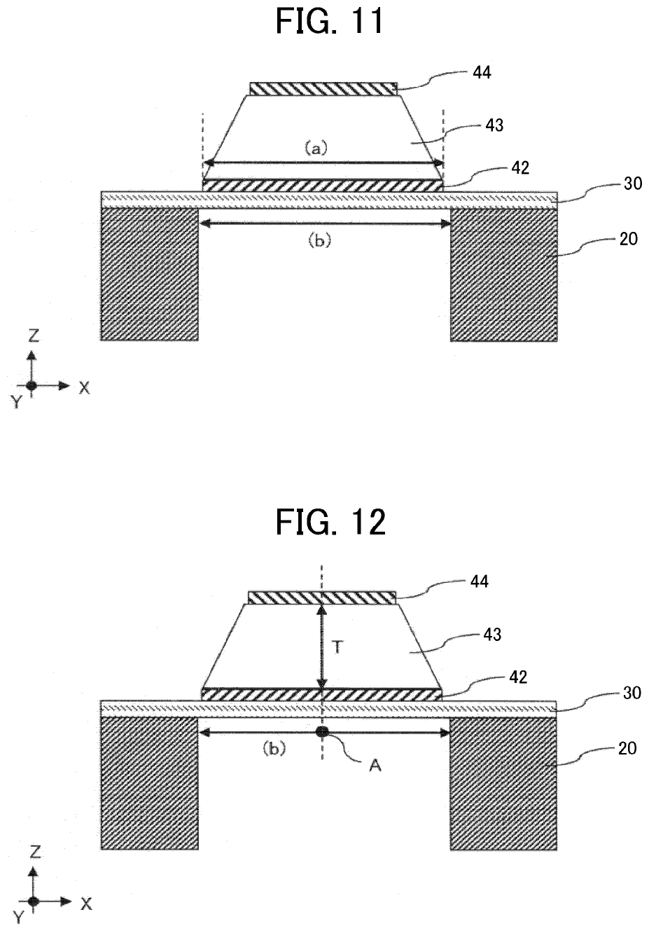

FIG. 11 depicts one example of the electromechanical transducer element. FIG. 11 is a sectional view similar to FIG. 1. However, the stacking structure of the electromechanical transducer film 43 is not illustrated. In the present example, when a region in which the diaphragm 30 vibrates is defined as the vibration region, the electromechanical transducer film 43 has a length (a) in the surface direction on the first electrode 42 side equal to or less than a length (b) in the surface direction in the vibration region of the diaphragm 30 in a cross section along the stacking direction.

The “stacking direction” is a direction in which the diaphragm 30, the first electrode 42, the electromechanical transducer film 43, the second electrode 44, and the like are stacked, and is a stacking direction in the stacking structure of the electromechanical transducer film 43. The “cross section along the stacking direction” is a cross section along the X-axis (lateral or short direction), the Y-axis (longitudinal direction), or the like, and is a cross section along the X-axis (lateral or short direction) in FIG. 11. Here, the “surface direction” refers to a direction along the surface of the substrate 20, the surface of the diaphragm 30, or the like. In other words, the stacking direction is a direction perpendicular to a direction in which the diaphragm 30, the first electrode 42, the electromechanical transducer film 43, the second electrode 44, and the like are stacked. In addition, the “vibration region” is a portion in which the diaphragm 30 vibrates, and refers to a region in which vibration is not inhibited by the substrate 20 forming the wall surface of the pressure chamber.

According to the present example, by setting (a)≤(b), the piezoelectric displacement of the electromechanical transducer element is not restricted by a region (also referred to as a non-vibration region) of the diaphragm corresponding to the substrate 20 forming the wall surface of the pressure chamber, and good piezoelectric displacement can be ensured. Thus, the amount of displacement of the electromechanical transducer element can be further enhanced.

In the present example, it is preferable that the length (a) in the surface direction on the first electrode 42 side is the same as the length (b) in the surface direction in the vibration region of the diaphragm 30. That is, it is preferable that the length (a) is equal to the length (b). In this case, the length of the electromechanical transducer film in the surface direction can be increased while preventing the piezoelectric displacement of the electromechanical transducer element from being restricted by the non-vibration region, and the amount of displacement can be further enhanced.

Next, another example of the present embodiment is described. FIG. 12 depicts the present example. FIG. 12 is a sectional view similar to FIG. 11. In the present example, when a region in which the diaphragm 30 vibrates is defined as a vibration region, the thickness of the electromechanical transducer film 43 is maximized at a center position A of a length (b) in a surface direction in the vibration region of the diaphragm 30 in a cross section along the stacking direction.

In FIG. 12, the thickness of the electromechanical transducer film 43 is represented by T, and the center position of the length (b) in the surface direction in the vibration region of the diaphragm 30 is represented by A. In the present example, the thickness T is maximum at the position A.

According to the present example, since the maximum film thickness of the electromechanical transducer film is maximized at the center position A of the vibration region in the surface direction, the displacement efficiency with respect to the film thickness of the electromechanical transducer film can be further enhanced, and the amount of displacement can be further enhanced.

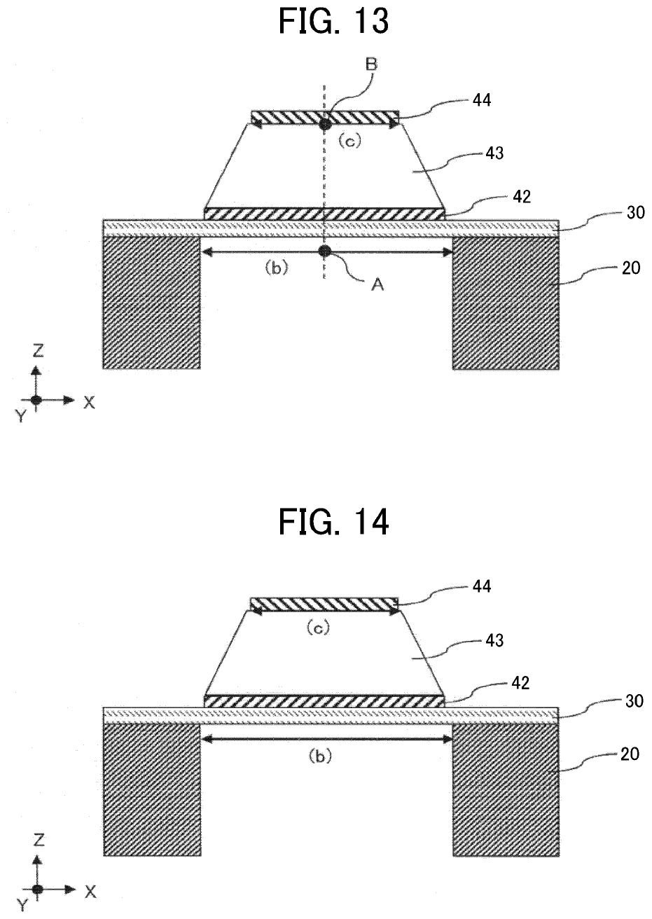

Next, another example of the present embodiment is described. FIG. 13 depicts the present example. FIG. 13 is a sectional view similar to FIG. 11. In the present example, when a region in which the diaphragm 30 vibrates is defined as a vibration region, in a cross section of the electromechanical transducer film 43 along the stacking direction, a center position B of a length (c) in the surface direction in a portion having the maximum film thickness coincides with a center position A of a length (b) in the surface direction in the vibration region of the diaphragm 30 in the surface direction.

In the present example, in the electromechanical transducer film 43, the length (c) in the surface direction in the portion having the maximum film thickness corresponds to the length (c) in the surface direction on the second electrode 44 side. According to the present example, similarly to the above-described example, the maximum film thickness of the electromechanical transducer film is maximized at the center position A of the vibration region in the surface direction. Thus, the displacement efficiency with respect to the film thickness of the electromechanical transducer film can be enhanced and the amount of displacement can be further enhanced.

Next, another example of the present embodiment is described. FIG. 14 depicts the present example. FIG. 14 is a sectional view similar to FIG. 11. In the present example, when a region in which the diaphragm 30 vibrates is defined as a vibration region, the electromechanical transducer film 43 has a ratio of a length (c) in a surface direction in a portion having a maximum film thickness to a length (b) in the surface direction in the vibration region of the diaphragm 30 of 1:4 to 1:2 in a cross section along the stacking direction.

In the present example, in the electromechanical transducer film 43, the length (c) in the surface direction in the portion having the maximum film thickness corresponds to the length (c) in the surface direction on the second electrode 44 side. When the ratio of the length (c) to the length (b), that is, the ratio of the top side to the bottom side in the electromechanical transducer film 43 is 1:4 to 1:2, as in the above example, the displacement efficiency with respect to the film thickness of the electromechanical transducer film can be further enhanced and the amount of displacement can be further enhanced.

In the plurality of examples described above, the short direction (X-axis direction) has been described, but the above-described configuration may also be applied to the longitudinal direction (Y-axis direction).

### Liquid Discharge Device and Liquid Discharge Apparatus

Next, a liquid discharging device and a liquid discharge apparatus are described.

A liquid discharge device according to an embodiment of the present disclosure includes a liquid discharge head according to an embodiment of the present disclosure. The liquid discharge head may be integrated with at least one of a head tank that stores liquid to be supplied to the liquid discharge head, a carriage on which the liquid discharge head is mounted, a supply mechanism that supplies liquid to the liquid discharge head, a maintenance recovery mechanism that maintains and recovers the liquid discharge head, and a main scanning movement mechanism that moves the liquid discharge head in main scanning directions indicated by arrow MSD in FIG. 5.

A liquid discharge apparatus of the present embodiment includes the liquid discharging head according to an embodiment of the disclosure or the liquid discharge device according to an embodiment of the disclosure.

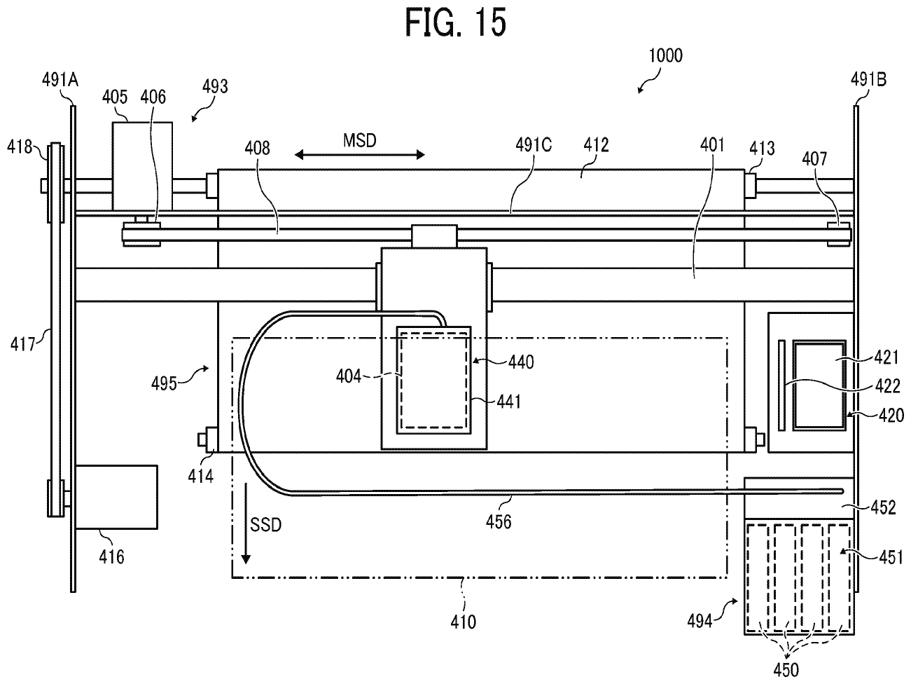

The liquid discharge apparatus according to an embodiment of the present disclosure is described in detail below with reference to FIGS. 15 and 16. FIG. 15 is a plan view of a main part of the liquid discharge apparatus. FIG. 16 is a side view of the main part of the liquid discharge apparatus.

The liquid discharge apparatus 1000 is a serial-type apparatus in which a main-scanning moving mechanism 493 reciprocates a carriage 403 in the main scanning directions MSD. The main-scanning moving mechanism 493 includes a guide 401, a main-scanning motor 405, and a timing belt 408. The guide 401 is bridged between a left side plate 491A and a right side plate 491B to moveably hold the carriage 403. The main-scanning motor 405 reciprocates the carriage 403 in the main scanning direction via the timing belt 408 bridged between a drive pulley 406 and a driven pulley 407.

The carriage 403 is mounted with a liquid discharge device 440 according to an embodiment of the present disclosure including a liquid discharge head 404 and a head tank 441 as an single integrated unit. The liquid discharge head 404 of the liquid discharge device 440 discharges color liquids of, for example, yellow (Y), cyan (C), magenta (M), and black (K). The liquid discharge head 404 has nozzle arrays each including a plurality of nozzles 11 arranged in a sub-scanning direction indicated by arrow SSD in FIG. 15 that is orthogonal to the main scanning direction MSD. The liquid discharge head 404 is mounted on the liquid discharge device 440 with its discharge direction downward.

A supply mechanism 494 disposed outside the liquid discharge head 404 supplies liquid stored in liquid cartridges 450 to the head tank 441 of the liquid discharge head 404.

The supply mechanism 494 includes a cartridge holder 451 to hold the liquid cartridges 450, a tube 456, and a liquid feed unit 452 including a liquid feed pump. The liquid cartridges 450 are detachably mounted on the cartridge holder 451. The liquid feed unit 452 feeds the liquid from the liquid cartridge 450 to the head tank 441 via the tube 456.

The liquid discharge apparatus 1000 further includes a conveyance mechanism 495 to convey a sheet 410. The conveyance mechanism 495 includes a conveyance belt 412 serving as a conveyor and a sub-scanning motor 416 to drive the conveyance belt 412.

The conveyance belt 412 attracts the sheet 410 and conveys the sheet 410 to a position facing the liquid discharge head 404. The conveyance belt 412 is an endless belt stretched between a conveyance roller 413 and a tension roller 414. The sheet 410 can be attracted to the conveyance belt 412 by electrostatic attraction, air suction, or the like.

The conveyance belt 412 circumferentially moves in the sub-scanning direction SSD as the conveyance roller 413 is rotationally driven by the sub-scanning motor 416 via a timing belt 417 and a timing pulley 418.

On one side of the carriage 403 in the main scanning direction, a maintenance mechanism 420 that maintains and recovers the liquid discharge head 404 is disposed lateral to the conveyance belt 412.

The maintenance mechanism 420 includes a cap 421 to cap the nozzle surface (on which the nozzles 11 are formed) of the liquid discharge head 404 and a wiper 422 to wipe the nozzle surface.

The main-scanning moving mechanism 493, the supply mechanism 494, the maintenance mechanism 420, and the conveyance mechanism 495 are installed onto a housing including the left side plate 491A, the right side plate 491B, and a back plate 491C.

In the liquid discharge apparatus 1000 having the above-described configuration, the sheet 410 is fed and attracted onto the conveyance belt 412 and conveyed in the sub-scanning direction SSD by the circumferential movement of the conveyance belt 412.

The liquid discharge head 404 is driven in response to an image signal while moving the carriage 403 in the main scanning direction MSD to discharge the liquid onto the sheet 410 not in motion, thereby recording an image.

As described above, the liquid discharge apparatus 1000 includes the liquid discharge head 404 according to an embodiment of the present disclosure, thus allowing stable formation of high quality images.

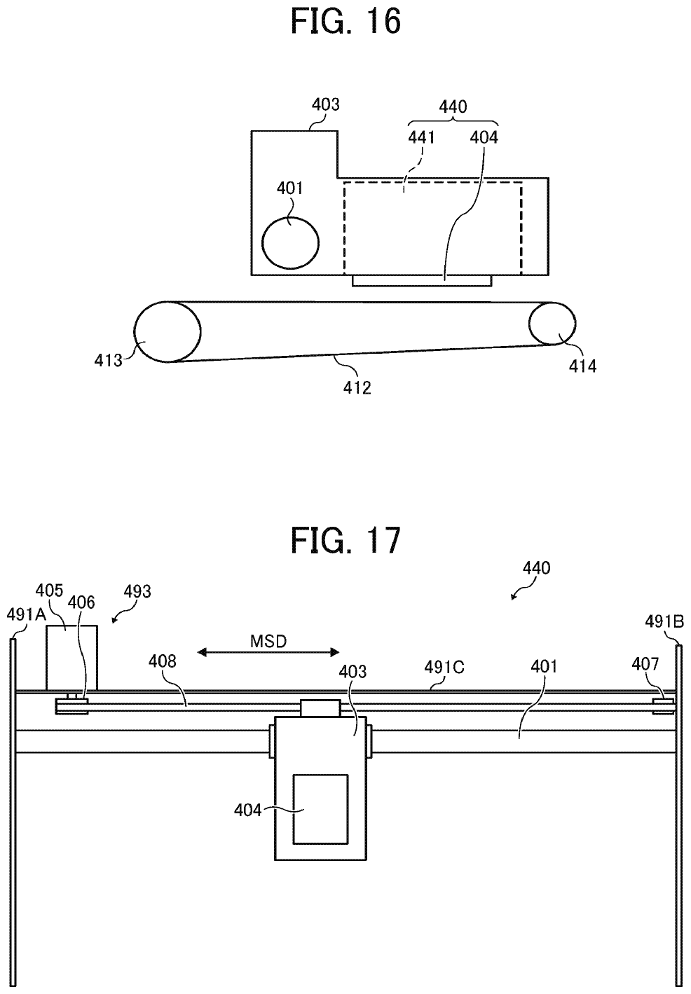

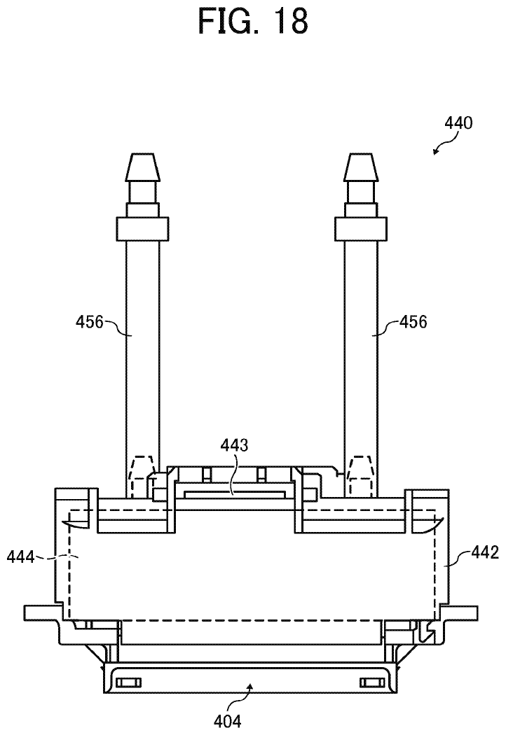

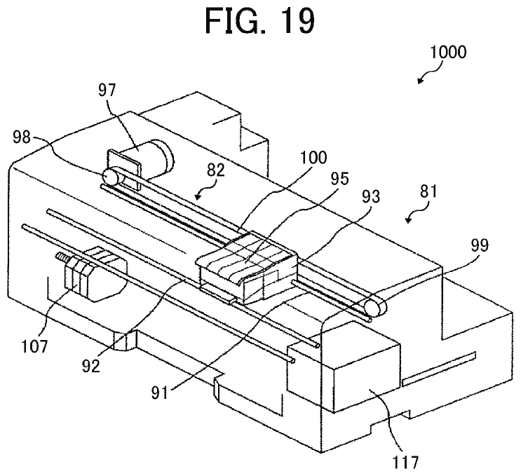

Next, another example of the liquid discharge device according to an embodiment of the present disclosure is described below with reference to FIG. 17. FIG. 17 is a plan view of a main part of the liquid discharge device.

This liquid discharge device 440 includes the housing including the side plates 491 A and 491B and the back plate 491C, the main-scanning moving mechanism 493, the carriage 403, and the liquid discharge head 404 of the above-described of the liquid discharge apparatus 1000.

The liquid discharge device 440 may further include at least one of the maintenance mechanism 420 and the supply mechanism 494, which may be attached to the side plate 491B.

Next, another example of the liquid discharge device according to an embodiment of the present disclosure is described below with reference to FIG. 18. FIG. 18 is a front view of a main part of the liquid discharge device.

The liquid discharge device 440 includes the liquid discharge head 404 to which a channel component 444 is attached and the tube 456 connected to the channel component 444.

The channel component 444 is disposed inside a cover 442. The liquid discharge device 440 may include the head tank 441 instead of the channel component 444. A connector 443 for electrically connecting to the liquid discharge head 404 is provided on the channel component 444.

In the above-described embodiments of the present disclosure, the liquid discharge apparatus includes the liquid discharge head or the liquid discharge device, and drives the liquid discharge head to discharge liquid. Examples of the liquid discharge apparatus include an apparatus capable of discharging liquid to a material to which liquid can adhere and an apparatus to discharge liquid toward gas or into liquid.

The liquid discharge apparatus can include at least one of devices for feeding, conveying, and discharging a material to which liquid can adhere. The liquid discharge apparatus can further include at least one of a pretreatment apparatus and a post-treatment apparatus.

The liquid discharge apparatus may be, for example, an image forming apparatus to form an image on a sheet by discharging ink, or a three-dimensional fabricating apparatus (solid-object fabricating apparatus) to discharge a fabrication liquid to a powder layer in which powder material is formed in layers, so as to form a three-dimensional fabrication object (solid fabrication object).

The liquid discharge apparatus is not limited to an apparatus to discharge liquid to visualize meaningful images, such as letters or figures. For example, the liquid discharge apparatus may be an apparatus to form meaningless images, such as meaningless patterns, or fabricate three-dimensional images.

The above-described term “material on which liquid can be adhered” represents a material on which liquid is at least temporarily adhered, a material on which liquid is adhered and fixed, or a material into which liquid is adhered to permeate. Examples of the “material on which liquid can be adhered” include recording media, such as paper sheet, recording paper, recording sheet of paper, film, and cloth, electronic component, such as electronic substrate and piezoelectric element, and media, such as powder layer, organ model, and testing cell. The “material on which liquid can be adhered” includes any material on which liquid is adhered, unless particularly limited.

The substance to which a liquid is adherable may be made of any material to which a liquid is at least temporarily adherable, such as paper, thread, fiber, cloth, laser, metal, plastic, glass, wood, ceramic, a building material such as wall paper or flooring material, and textile for clothing.

Examples of the “liquid” include ink, treatment liquid, DNA sample, resist, pattern material, binder, modeling liquid, and solution or liquid dispersion containing amino acid, protein, or calcium.

The liquid discharge apparatus may be an apparatus to relatively move a liquid discharge head and a material on which liquid can be adhered. However, the liquid discharge apparatus is not limited to such an apparatus. For example, the liquid discharge apparatus may be a serial head apparatus that moves the liquid discharge head or a line head apparatus that does not move the liquid discharge head.

Examples of the liquid discharge apparatus further include: a treatment liquid applying apparatus that discharges a treatment liquid onto a paper sheet to apply the treatment liquid to the surface of the paper sheet, for reforming the surface of the paper sheet; and an injection granulation apparatus that injects a composition liquid, in which a raw material is dispersed in a solution, through a nozzle to granulate fine particle of the raw material.

In the present disclosure, a “liquid discharge device” refers to a liquid discharge head integrated with functional components/mechanisms, i.e., an aggregation of components related to liquid discharge. For example, the “liquid discharge device” includes a combination of the liquid discharge head with at least one of a head tank, a carriage, a supply unit, a maintenance unit, and a main scan moving unit.

Here, the integrated unit may also be a combination in which the liquid discharge head and a functional part(s) are secured to each other through, e.g., fastening, bonding, or engaging, or a combination in which one of the liquid discharge head and a functional part(s) is movably held by another. The liquid discharge head may be detachably attached to the functional part(s) or unit(s) s each other.

Examples of the liquid discharge device include the liquid discharge device 440 in which a liquid discharge head and a head tank are integrated, as illustrated in FIG. 16. The liquid discharge head and the head tank may be connected each other via, e.g., a tube to integrally form the liquid discharge device. Here, a unit including a filter may further be added to a portion between the head tank and the liquid discharge head.

In another example, the liquid discharge device may be an integrated unit in which a liquid discharge head is integrated with a carriage.

In still another example, the liquid discharge device includes the liquid discharge head movably held by a guide that forms part of a main scan moving unit, so that the liquid discharge head and the main scan moving unit are integrated as a single integrated unit. Examples of the liquid discharge device further include those in which a liquid discharge head, a carriage, and a main-scanning moving mechanism are integrated, as illustrated in FIG. 17.

In another example, the cap that forms part of the maintenance unit is secured to the carriage mounting the liquid discharge head so that the liquid discharge head, the carriage, and the maintenance unit are integrated as a single unit to form the liquid discharge device.

Examples of the liquid discharge device further include those in which a liquid discharge head and a supply mechanism are integrated in such a manner that a head tank or channel component is mounted on the liquid discharge head and a tube is connected to the liquid discharge head, as illustrated in FIG. 18.

The main-scanning moving mechanism may be a guide only. The supply mechanism may be a tube(s) only or a loading unit only.

The liquid discharge head is not limited in the type of pressure generator used. For example, the above-described piezoelectric actuator (which may use a laminated piezoelectric element), a thermal actuator using an electrothermal transducer such as a heating resistor, and an electrostatic actuator comprising a diaphragm and a counter electrode.

In the present disclosure, “image forming”, “recording”, “printing”, “fabrication”, etc. are treated as synonymous terms.

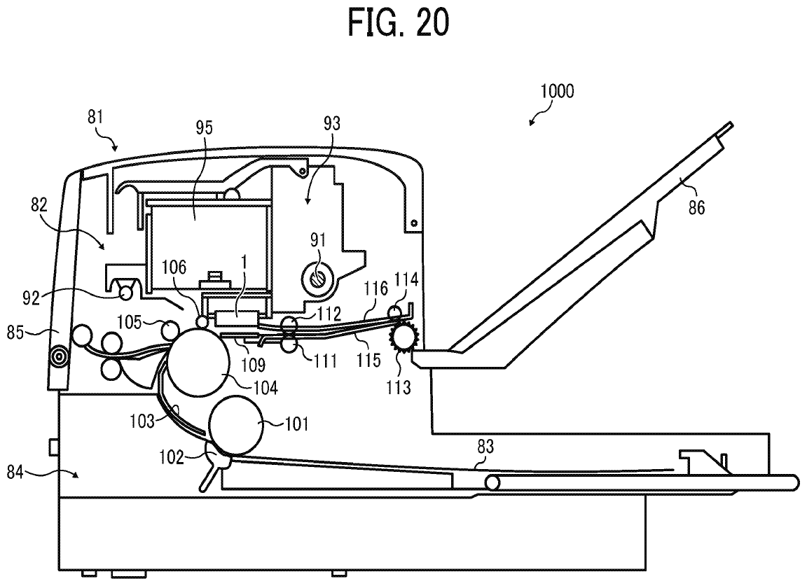

Next, an example of a liquid discharge apparatus including a liquid discharge head according to an embodiment of the present disclosure is described with reference to FIGS. 19 and 20. FIG. 19 is a perspective view of the liquid discharge apparatus according to the present embodiment. FIG. 20 is a side view of a mechanism section of the liquid discharge apparatus.

Here, an inkjet recording apparatus is described as an example of the liquid discharge apparatus. The liquid discharge apparatus 1000 according to the present embodiment includes, e.g., a printing mechanism 82 that includes a carriage 93, recording heads 94, ink cartridges 95, and the like. The carriage 93 is movable in main scanning directions inside an apparatus body 81. The recording heads 94 according to the present embodiment are inkjet heads mounted on the carriage 93. The ink cartridges 95 supply ink to the recording heads 94. A sheet feed cassette (or a sheet feed tray) 84 is mounted in a lower part of the apparatus body 81 to be insertable into and removable from the lower part of the apparatus body 81. Sheets 83 are loadable onto the sheet feed cassette 84 from the front side of the apparatus body 81. In addition, a bypass tray 85 for manually feeding sheets 83 is disposed to be tiltable to open. The liquid discharge apparatus 1000 takes in a sheet 83 fed from the sheet feed cassette 84 or the bypass tray 85, records an image by a printing mechanism 82, and discharges the sheet 83 to a sheet ejection tray 86 mounted on the rear surface side.

In the printing mechanism 82, a main guide rod 91 and a sub-guide rod 92 as guides laterally bridged between left and right side plates support the carriage 93 slidably in the main scanning direction. The recording heads 94 to discharge ink droplets of respective colors of yellow (Y), cyan (C), magenta (M), and black (Bk) are mounted on the carriage 93 so that a plurality of ink discharge ports (nozzles) of each nozzle row are arranged in a direction perpendicular to the main scanning direction. The recording heads 94 are mounted on the carriage 93 in such a direction that ink droplets are discharged downward.

The ink cartridges 95 to supply ink of the respective colors to the recording heads 94 are replaceably mounted on the carriage 93. Each of the ink cartridges 95 includes an air communication port communicated with the atmosphere in an upper portion of each ink cartridge 95, an ink supply port in a lower portion of each ink cartridge 95, and a porous body to be filled with ink inside each ink cartridge 95. Each of the ink cartridges 95 maintains the ink supplied to the recording head 94 at a slight negative pressure by the capillary force of the porous body. In this example, the plurality of recording heads 94 is used as the recording heads of the liquid discharge apparatus. However, in some embodiments, a single head having nozzles to discharge different colors of ink droplets may be used as the recording head.

In the present embodiment, a rear side (a downstream side in a sheet conveyance direction) of the carriage 93 is slidably fitted to the main guide rod 91, and a front side (an upstream side in a sheet conveyance direction) of the carriage 93 is slidably mounted to the sub-guide rod 92. To move the carriage 93 for scanning in the main scanning direction, a timing belt 100 is stretched taut between a driving pulley 98 rotated by a main scanning motor 97 and a driven pulley 99. The timing belt 100 is secured to the carriage 93, and the carriage 93 is driven to reciprocate according to forward and reverse rotation of the main scanning motor 97.

To convey the sheets 83 set on the sheet feeding cassette 84 to below the recording heads 94, the liquid discharge apparatus 1000 includes a sheet feeding roller 101, a friction pad 102, a sheet guide 103, a conveyance roller 104, a conveyance roller 105, and a leading end roller 106. The sheet feeding roller 101 and the friction pad 102 separate and feed a sheet 83 from the sheet feeding cassette 84. The sheet guide 103 guides the sheet 83. The conveyance roller 104 turns over and conveys the fed sheet 83. The conveyance roller 105 is pressed against the circumferential surface of the conveyance roller 104. The leading end roller 106 defines the feed angle of the sheet 83 from the conveyance roller 104. The conveyance roller 104 is driven to rotate by a sub-scanning motor 107 via a gear train.

The liquid discharge apparatus 1000 further includes a print receiver 109 disposed below the recording heads 94. The print receiver 109 is a sheet guide to guide a sheet 83, which is fed from the conveyance roller 104, in a range corresponding to a range of movement of the carriage 93 in the main scanning direction. On the downstream side of the print receiver 109 in a sheet conveyance direction are disposed a conveyance roller 111, which is driven to rotate so as to feed the sheet 83 in a sheet ejecting direction, and a spur roller 112. The liquid discharge apparatus 1000 further includes a sheet ejection roller 113 and a spur roller 114 to feed a sheet 83 to the sheet ejection tray 86 and guides 115 and 116 constituting a sheet ejection passage.

In recording, the liquid discharge apparatus 1000 drives the recording heads 94 in response to image signals while moving the carriage 93, discharges ink to the stopped sheet 83 to record one line of a desired image on the sheet 83, feeds the sheet 83 in a predetermined amount, and then records a next line on the sheet 83. In response to a recording end signal or a signal indicating that the rear end of the sheet 83 has reached a recording area, the recording operation is ended and the sheet 83 is ejected.

Further, the liquid discharge apparatus 1000 further includes a recovery device 117 to recover the recording heads 94 from a discharge failure. The recovery device 117 is disposed at a position outside a recording area at the right end in the direction of movement of the carriage 93. The recovery device 117 includes a cap unit, a suction unit, and a cleaning unit. During standby for printing, the carriage 93 is moved toward the recovery device 117 and the recording heads 94 are capped with the cap unit. Thus, discharge ports are maintained in humid state, thus preventing discharge failure due to dry of ink. For example, during recording, the liquid discharge apparatus 1000 discharges ink not relating to the recording to maintain the viscosity of ink in all of the discharge ports constant, thus maintaining stable discharging performance.

In the case failure occurs, the discharge ports (nozzles) of the recording head 94 are sealed by the capping unit, air bubbles and the like are sucked from the discharge ports by the suction unit through the tube, and the ink, dust, and the like adhering to the discharge port surface are removed by the cleaning unit to recover the discharge failure. The sucked ink is drained to a waste ink container disposed on a lower portion of the apparatus body, and is absorbed into and retained in an ink absorber of the waste ink container.

As described above, since the liquid discharge head and the liquid discharge apparatus according to embodiments of the present disclosure include the electromechanical transducer element according to an embodiment of the present disclosure, the liquid discharge head and the liquid discharge apparatus according to embodiments of the present disclosure have good piezoelectric characteristics and dielectric strength, and few failures occur. Such a configuration can prevent an ink droplet discharge failure due to a diaphragm drive failure and to restrain variations in displacement. Accordingly, stable ink droplet discharge characteristics can be obtained and image quality is enhanced.

### Examples

Further understanding can be obtained by reference to certain specific examples which are provided herein for the purpose of illustration only and are not intended to be limiting.

### Example 1

As illustrated in FIG. 6A, the silicon oxide diaphragm 30 was stacked on the surface of the substrate 20 using silicon, and the adhesion layer 41 and the first electrode 42 were sequentially stacked by sputtering. TiO₂ having a thickness of 50 nm was used for the adhesion layer 41. Pt having a thickness of 250 nm was used for the first electrode 42.

Next, the entire surface of the first electrode 42 was coated with the precursor sol-gel solution of the electromechanical transducer film by spin coating to form a coating film.

In the precursor sol-gel solution used, lead acetate-3-hydrate and titanium isopropoxide were used as starting materials. First, water of crystallization of lead acetate was dissolved in 2-methoxyethanol and then dehydrated, and then titanium isopropoxide was dissolved in methoxyethanol to proceed alcohol exchange reaction and esterification reaction. A precursor sol-gel solution of lead titanate (PT) was synthesized by mixing with the methoxyethanol solution in which lead acetate was dissolved. The concentration of solutes in the precursor sol-gel solution was 0.05 mol/1.

The substrate 20 having the coating film formed on the first electrode 42 was heated from the lower surface side of the substrate 20 by a hot plate at a first heating temperature (120° C.) to dry the solvent component. Thus, as illustrated in FIG. 6B, a seed layer 430a made of an amorphous lead titanate (PT) gel film containing an organic substance on the first electrode 42 to a thickness of about 6 nm.

Next, the precursor sol-gel solution of the electromechanical transducer film was applied to the entire surface of the seed layer 430a by spin coating to form a coating film.

The precursor sol-gel solution used here was prepared as follows. Water of crystallization of lead acetate was dissolved in 2-methoxyethanol and then dehydrated. Subsequently, zirconium propoxide and titanium isopropoxide were dissolved in methoxyethanol, and an alcohol exchange reaction and an esterification reaction were proceeded. A precursor sol-gel solution of lead zirconate titanate (PZT) was synthesized by mixing with the methoxyethanol solution in which lead acetate was dissolved. The concentration of solutes in the precursor sol-gel solution was 0.5 mol/1.

Thus, as illustrated in FIG. 6C, the precursor coating film 430b was stacked on the seed layer 430a. That is, the precursor coating film 430b was uniformly formed on the seed layer 430a.

Next, a heat treatment step was performed. In the heat treatment step, first, heat treatment was performed at a first heating temperature (about 120° C.) as a drying step to dry the solvents of the precursor coating film 430b. Next, the organic substances contained in the precursor coating film 430b were thermally decomposed at a second heating temperature (about 500° C.). In order to crystallize the precursor coating film 430b together with the amorphous seed layer 430a, rapid thermal annealing (RTA) was performed at a third heating temperature (about 700° C.). Thus, as illustrated in FIG. 7A, the seed layer 430a and the precursor coating film 430b were integrated to obtain the electromechanical transducer film 43. At this time, the thickness of the electromechanical transducer film 43 including the seed layer was 85 nm, and no crack was generated in the film.

Next, similarly to the step illustrated in FIG. 6C, the precursor sol-gel solution was applied to the entire surface of the electromechanical transducer film 43 by spin coating, and the heat treatment step described with reference to FIG. 7A was performed to form and stack another layer of electromechanical transducer film. Thus, the thickness of the electromechanical transducer film 43 was increased to about 160 nm, and it was confirmed that no crack was generated in the film.

Then, the steps illustrated in FIGS. 6C and 7A were repeated 35 times to obtain an electromechanical transducer film 43 having a thickness of about 3.0 μm (FIG. 7B). It was confirmed that no crack or the like occurred in the obtained electromechanical transducer film 43.

Next, as illustrated in FIG. 7C or FIG. 9A, a Pt film having a thickness of 250 nm was formed as the second electrode 44 on the electromechanical transducer film 43 by sputtering.

Next, a photoresist material was uniformly applied onto the second electrode 44 to form a photoresist layer 50 having a thickness of 10 μm. The photoresist layer 50 was positioned and shaped as illustrated in FIG. 9B. Unnecessary portions of the electromechanical transducer film 43 and the second electrode 44 are exposed by photolithography, and the photoresist layer 50 is formed at a desired position for forming an electromechanical transducer element to form a resist pattern. The cross-sectional shape of the photoresist layer 50 along the short direction (X-axis direction) was tapered, and the bottom side was 45 μm and the top side was 25 μm. The interval between adjacent photoresist layers 50 was 45 μm. In the cross section along the longitudinal direction (Y-axis direction), the cross-sectional shape was rectangular, and both the bottom side and the top side were 1000 μm. A resist pattern including a plurality of photoresist layers 50 having such a shape was formed.

Then, unnecessary portions of the electromechanical transducer film 43 and the second electrode 44 were removed by dry etching to perform patterning. The patterned second electrodes 44 are individual electrodes. Thus, an electromechanical transducer element having the electromechanical transducer film 43 of a tapered shape as illustrated in FIG. 9C was obtained. The obtained electromechanical transducer element has a rectangular pattern having a longitudinal length of 1000 μm when viewed from above. In addition, the cross-sectional shape of the electromechanical transducer film 43 in the obtained electromechanical transducer element was a tapered shape having a bottom side of 45 μm and an upper side of 25 μm along the short direction (X-axis direction).

### Comparative Example 1

Comparative Example 1 is the same as Example 1 except that the photoresist layer 50 in Example 1 was replaced by a rectangular photoresist layer 50a as illustrated in the sectional view of FIG. 10B. The photoresist layer 50a has a thickness of 45 μm on both the bottom side and the top side in the lateral direction. Then, etching was performed in the same manner as in Example 1 to produce an electromechanical transducer element illustrated in FIG. 10C. The electromechanical transducer film 43a in the obtained electromechanical transducer element had a cubic shape in which both the bottom side and the top side in the lateral direction were 45 μm.

### Measurement and Evaluation Electrical Characteristics, Piezoelectric Constant, and Displacement Amount

The obtained electromechanical transducer element is a lateral vibration (vent mode) type electromechanical transducer element (piezo element) using deformation in the d31 direction. When the electromechanical transducer element obtained in Example 1 was evaluated for electrical characteristics, the relative dielectric constant of the electromechanical transducer film 43 was 1280, the dielectric loss was 0.02, the residual polarization was 19.1 μC/cm², and the coercive electric field was 36. 2 kV/cm. Therefore, good electrical characteristics are obtained.

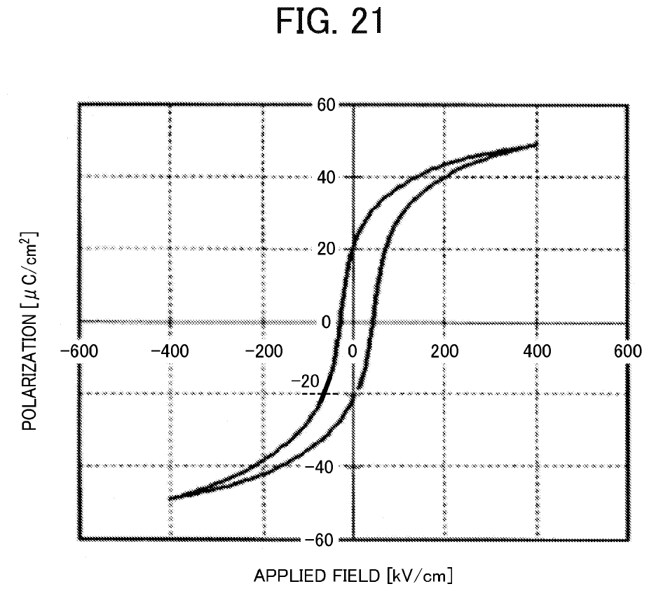

The P-E hysteresis curve obtained in this case is illustrated in FIG. 21. As illustrated in FIG. 21, a good hysteresis curve is obtained.

Next, with respect to the electromechanical transducer elements obtained in Example 1 and Comparative Example 1, the back surface side of the substrate 20 was subjected to photolithography and dry etching of the back surface side of the substrate to produce the shapes illustrated in FIGS. 4A and 4B. In FIGS. 4A and 4B, the adhesive layer is not illustrated.

Here, in both Example 1 and Comparative Example 1, the length of both end portions of the electromechanical transducer film 43 in the cross-sectional direction on the diaphragm 30 side is the same as the length of the vibration region of the diaphragm. That is, in FIG. 12, the length (a) in the surface direction on the first electrode 42 side and the length (b) in the surface direction in the vibration region of the diaphragm 30 are set to be the same. In both Example 1 and Comparative Example 1, as illustrated in FIG. 13, the thickness of the electromechanical transducer film 43 was maximized at the center position A of the length (b) in the surface direction in the vibration region of the diaphragm 30.

With respect to Example 1 configured as illustrated in FIG. 4A, the electromechanical conversion capability (piezoelectric constant d31) was evaluated. The piezoelectric constant d31 was calculated by measuring the amount of deformation due to application of an electric field with a laser Doppler vibrometer and further performing matching by simulation. The obtained piezoelectric constant d31 was 128 pm/V, which is a characteristic value that can be sufficiently designed as a liquid discharge head.

Next, the amount of displacement of the electromechanical transducer film 43 in each of the electromechanical transducer elements obtained in Example 1 and Comparative Example 1 was measured with a laser Doppler meter. As a result, as illustrated in FIG. 5, the amount of displacements in Example 1 are as illustrated in 4A and 4C, and the amount of displacements in Comparative Example 1 are as illustrated in 4B and 4D. As described above, in Example 1, the diaphragm 30 in the vicinity of an end portion was deformed more greatly than in Comparative Example 1, and the maximum amount of displacement of the central portion of the electromechanical transducer film was also larger than in Comparative Example 1.

### Thickening

In Example 1, an attempt was made to further increase the thickness of the electromechanical transducer film 43 without disposing the second electrode. That is, the above-described application of the precursor sol-gel solution by the spin coating method and crystallization of the electromechanical transducer film 43 by the heat treatment were further repeated, and then photolithography and dry etching were performed. As a result, a patterned electromechanical transducer film 43 having a tapered shape and a film thickness of 10 μm was obtained. The obtained electromechanical transducer film 43 did not have defects such as cracks. This film thickness is a film thickness at which it is extremely difficult to maintain a cylindrical (substantially meniscus) shape pattern when the film thickness is formed by a typical inkjet method.

The above-described embodiments are illustrative and do not limit the present disclosure. In addition, the embodiments and modifications or variations thereof are included in the scope and the gist of the invention, and are included in the invention described in the claims and the equivalent scopes thereof. For example, elements and/or features of different illustrative embodiments may be combined with each other and/or substituted for each other within the scope of the present disclosure.

Any one of the above-described operations may be performed in various other ways, for example, in an order different from the one described above.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), and conventional circuit components arranged to perform the recited functions.

1. An electromechanical transducer element, comprising:
a first electrode on a diaphragm;
an electromechanical transducer film on the first electrode; and
a second electrode on the electromechanical transducer film,
the electromechanical transducer film having a stacking structure,
the electromechanical transducer film having a linear tapered shape that narrows from a first side facing the first electrode to a second side facing the second electrode in a cross section along a stacking direction.

2. The electromechanical transducer element according to claim 1,
wherein, when a region in which a diaphragm vibrates is defined as a vibration region, a length of the electromechanical transducer film in a surface direction on the first side facing the first electrode is equal to or less than a length in the surface direction in the vibration region of the diaphragm, in the cross section along the stacking direction.

3. The electromechanical transducer element according to claim 1,
wherein, when a region in which a diaphragm vibrates is defined as a vibration region, the electromechanical transducer film has a maximum thickness at a center position of a length in a surface direction in the vibration region of the diaphragm, in the cross section along the stacking direction.

4. The electromechanical transducer element according to claim 1,
wherein, when a region in which the diaphragm vibrates is defined as a vibration region, a center position of a length in a surface direction in a portion of the electromechanical transducer film having a maximum film thickness and a center position of a length in the surface direction in the vibration region of the diaphragm coincide with each other in the surface direction, in the cross section along the stacking direction.

5. The electromechanical transducer element according to claim 1,
wherein, when a region in which the diaphragm vibrates is defined as a vibration region, a ratio of a length in a surface direction in a portion of the electromechanical transducer film having a maximum film thickness to a length in the surface direction in the vibration region of the diaphragm is 1:4 to 1:2 in the cross section along the stacking direction.

6. The electromechanical transducer element according to claim 1,
wherein the electromechanical transducer film has a longitudinal side and a short side shorter than the longitudinal side when the electromechanical transducer element is viewed from a direction perpendicular to a surface direction of the electromechanical transducer element, and
wherein the cross section along the stacking direction is a cross section along the short side.

7. A liquid discharge head, comprising:
a nozzle configured to discharge liquid;
a pressure chamber communicating with the nozzle; and
the electromechanical transducer element according to claim 1 configured to generate pressure in liquid in the pressure chamber.

8. A liquid discharge device, comprising the liquid discharge head according to claim 7.

9. The liquid discharge device according to claim 8,
wherein the liquid discharge head is integrated with at least one of:
a head tank configured to store liquid to be supplied to the liquid discharge head;
a carriage on which the liquid discharge head is mounted;
a supply mechanism configured to supply liquid to the liquid discharge head;
a maintenance mechanism configured to maintain and recover the liquid discharge head; and
a main-scanning moving mechanism configured to move the liquid discharge head in a main scanning direction.

10. A liquid discharge apparatus, comprising the liquid discharge device according to claim 8.

11. A liquid discharge apparatus, comprising the liquid discharge head according to claim 7.

12. A method of making an electromechanical transducer element, the method comprising:
forming a first electrode on a diaphragm,
forming an electromechanical transducer film on the first electrode; and
forming a second electrode on the electromechanical transducer film,
wherein the forming the electromechanical transducer film includes:
forming the electromechanical transducer film having a stacked structure by a spin coating method; and
forming a linear tapered shape that narrows from a first side facing the first electrode to a second side facing the second electrode in a cross section of the electromechanical transducer film along a stacking direction.
